(19) United States
(12) Patent Application Publication
(10) Pub. No.: US 2026/0045288 A1
(43) Pub. Date: Feb. 12, 2026

(54) COMPUTE-IN-MEMORY CELL AND ARRAY WITH CAPACITIVE ACCUMULATION AND NONVOLATILE MEMORY TRANSISTOR

(71) Applicants: University of Notre Dame du Lac, South Bend, IN (US); The Penn State Research Foundation, University Park, PA (US)

(72) Inventors: Kai Ni, Notre Dame, IN (US); Vijaykrishnan Narayanan, State College, PA (US); Yixin Xu, State College, PA (US)

(21) Appl. No.: 19/216,231

(22) Filed: May 22, 2025

Related U.S. Application Data
(60) Provisional application No. 63/679,890, filed on Aug. 6, 2024.

(51) Int. Cl. G11C 11/22

(52) U.S. Cl. CPC G11C 11/2273; G11C 11/221; G11C 11/2259; G11C 11/2297

(57) ABSTRACT

A CiM architecture is disclosed, including memory cells each having a nonvolatile memory transistor and a capacitor connected in series between a bit line and a sense node. The transistor is configured to store a programmable state corresponding to a weight value and to selectively conduct based on a control voltage applied to a gate terminal. During a charging phase, the capacitor accumulates charge based on the conduction state of the transistor and an input voltage applied to the bit line. During a compute phase, the sense node exchanges charge with one or more other sense nodes in the array, such that a resulting voltage reflects an analog output of a MAC operation. The disclosed architecture can support binary and/or multi-bit computation and, in some cases, can utilize FeFETs or other nonvolatile devices to perform in-memory operations with improved variation resilience and energy efficiency.

### RELATED APPLICATIONS

The present application claims priority benefit to U.S. Provisional App. No. 63/679,890, entitled “CHARGE-DOMAIN COMPUTE-IN-MEMORY ARRAY UTILIZING MULTI-LEVEL CELL SENSING WITH FERROELECTRIC FIELD-EFFECT TRANSISTORS,” filed Aug. 6, 2024, which is hereby incorporated herein by reference in its entirety.

### STATEMENT OF GOVERNMENT SUPPORT

This invention was made with government support under Grant Nos. 2235366 and CCF2344819 awarded by the National Science Foundation, under Grant No. DE-SC0021118 awarded by the Department of Energy and under Grant No. HR0011-23-3-0002 awarded by Department of Defense/Defense Advanced Research Projects Agency (DARPA). The Government has certain rights in the invention.

### FIELD

The present disclosure relates generally to compute-in-memory (CiM) architectures, and more specifically to memory arrays and methods that utilize nonvolatile memory transistors and capacitive storage elements to perform in-memory computation.

### BACKGROUND

In some computing architectures, such as those based on the von Neumann model, memory and processing units are implemented as separate components. This physical and logical separation can introduce performance and energy inefficiencies due to frequent data transfers between memory and processing units.

CiM architectures have been explored as an alternative approach in which certain computational tasks can be performed within or near the memory array. CiM systems can utilize a range of memory technologies, including resistive random-access memory (ReRAM), phase-change memory (PCM), or volatile field-effect transistors (FETs), such as those used in dynamic random-access memory (DRAM).

In some CiM designs, the computation relies on sensing current through memory devices, which can demand precise control of device conductance. Variability in device characteristics may impact computational accuracy, particularly in systems using multi-level conductance states. In addition, current-mode sensing can impose tight constraints on peripheral circuits and increase susceptibility to noise and mismatch. These factors can limit the scalability, reliability, and energy efficiency of current-domain CiM implementations.

### SUMMARY

A CiM architecture is disclosed, including memory cells each having a nonvolatile memory transistor and a capacitor connected in series between a bit line and a sense node. The transistor is configured to store a programmable state corresponding to a weight value and to selectively conduct based on a control voltage applied to a gate terminal. During a charging phase, the capacitor accumulates charge based on the conduction state of the transistor and an input voltage applied to the bit line. During a compute phase, the sense node exchanges charge with one or more other sense nodes in the array, such that a resulting voltage reflects an analog output of a multiply-accumulate (MAC) operation. The disclosed architecture can support binary and/or multi-bit computation and, in some cases, can utilize ferroelectric field-effect transistors (FeFETs) or other nonvolatile devices to perform in-memory operations with improved variation resilience and energy efficiency.

### BRIEF DESCRIPTION OF THE DRAWINGS

FIG. 1A illustrates an example current-domain CiM design.

FIG. 1B illustrates an example charge-domain CiM design.

FIG. 1C illustrates that current-domain CiM designs can face challenges in maintaining computational accuracy for both binary and MLC operations due to sensitivity to conductance variations.

FIG. 1D illustrates that in charge-domain CiM, FeFETs can function as switches, allowing computation without relying on precise ON current values.

FIG. 1E illustrates an example 1FeFET-1C cell structure.

FIG. 1F illustrates example benefits of a 1FeFET1C-based charge-domain CiM design.

FIG. 2A illustrates an example CiM cell comprising a nonvolatile memory transistor and a capacitor electrically coupled in series.

FIG. 2B illustrates an example process flow for fabricating the CiM cell of FIG. 2A.

FIG. 2C illustrates an example top-view scanning electron microscopy (SEM) image of a fabricated CiM cell, such as the cell shown in FIG. 2A, including a FeFET and a capacitor.

FIG. 2D illustrates an example cross-sectional transmission electron microscopy (TEM) image of the FeFET gate stack in the CiM cell of FIG. 2A.

FIG. 2E illustrates an example elemental composition profile measured across the gate stack of the FeFET in the CiM cell of FIG. 2A.

FIG. 2F illustrates example memory window characteristics for the FeFET of FIG. 2A under positive and negative programming voltages.

FIG. 2G illustrates example current-voltage characteristics (I_D-V_G) for the FeFET in the CiM cell of FIG. 2A, showing four distinct threshold voltage states suitable for multi-level cell operation.

FIG. 2H illustrates example measured capacitance and leakage current characteristics of the capacitor in the 1FeFET1C cell of FIG. 2A.

FIGS. 3A-3C illustrate principles of an example of binary CiM operation using a 1FeFET1C cell array.

FIG. 4A illustrates an example CiM cell having the FeFET programmed to a low-threshold voltage state, enabling conduction between the terminals.

FIG. 4B illustrates an example waveform confirming that capacitor charging can occur when the FeFET is in the LVT state.

FIG. 4C illustrates an example CiM cell in which the FeFET is programmed to a high-threshold voltage state, inhibiting conduction.

FIG. 4D illustrates an example waveform showing suppression of capacitor charging when the FeFET is in the HVT state.

FIG. 4E illustrates example transient behavior of the bit line during charge sharing in a 1FeFET1C array.

FIG. 4F illustrates an example linear relationship between the number of FeFETs in the LVT state and the resulting bit line voltage.

FIG. 5A illustrates an example of parallel sensing mode in which a constant VG is applied and the output drain current is measured to identify different MLC states.

FIG. 5B illustrates an example of the probability density function of sensed current values for parallel sensing.

FIG. 5C illustrates an example of sequential sensing mode using multiple VG levels to selectively activate cells with different MLC states.

FIG. 5D illustrates an example of the sensed current distributions for the sequential sensing method.

FIG. 5E illustrates an example challenge in current-domain CiM using sequential sensing.

FIG. 6A illustrates an example configuration of a charge-domain CiM array that includes multiple 1FeFET1C cells, each configured to store a 2-bit MLC weight.

FIG. 6B illustrates an example charge-domain sensing condition for an applied word line voltage Vread1.

FIG. 6C illustrates an example sensing behavior at a second voltage level Vread2.

FIG. 6D illustrates a third example sensing step using a read voltage Vread3.

FIG. 7A illustrates an example four-cycle charge-domain operation using 1FeFET1C cells.

FIG. 7B illustrates an example set of FeFET transfer characteristics as a function of gate voltage VG.

FIG. 7C illustrates a summary of voltages applied during each operation cycle.

FIG. 8A illustrates an example top view scanning electron microscope image of a fabricated 1FeFET1C CiM array.

FIG. 8B illustrates example timing waveforms associated with the charge-domain MLC CiM operation.

FIG. 8C illustrates example transient voltage waveforms of a single 1FeFET1C cell during the charging process for different MLC states.

FIG. 8D illustrates an example of sensed voltage at the SN during the compute phase following charge sharing among four cells.

FIG. 9A illustrates an example of VBL behavior as a function of MAC output for an array of 1FeFET1C cells.

FIG. 9B illustrates an example Monte Carlo simulation result modeling the effect of threshold voltage variation in the 1FeFET1C charge-domain CiM array.

FIG. 9C illustrates an example of current-domain CiM behavior under the same VTH variation.

FIG. 9D illustrates an example of inference accuracy under varying VTH conditions.

FIG. 9E illustrates an example of output voltage variation when both VTH and cell capacitor variation are introduced.

FIG. 9F illustrates a comparison of architectural characteristics between charge-domain and current-domain CiM systems.

FIG. 9G illustrates an example configuration of a 128×128 1FeFET1C array and associated peripheral circuits used for benchmarking.

FIG. 9H illustrates a benchmarking comparison between a 1FeFET1C charge-domain array and other previously reported charge-domain CiM systems.

FIG. 10 illustrates a flow diagram illustrating an embodiment of routine, which can be implemented by a CiM system.

### DETAILED DESCRIPTION

Managing MAC operations efficiently within memory arrays is becoming increasingly relevant as artificial intelligence (AI) and edge computing systems continue to grow in complexity. Traditional CiM designs often rely on current-domain sensing mechanisms, which may require careful control of analog current values and can be sensitive to device-level variation. These limitations highlight the potential for CiM approaches that use alternative techniques for performing weighted computations inside memory arrays.

Some inventive concepts described herein relate to CiM cells that incorporate a nonvolatile memory transistor and a capacitor in series between a bit line and a sense node. In some examples, the transistor can be implemented using a FeFET, which retains a programmable threshold voltage state. The transistor can act as a switch that enables or blocks charge transfer during a charging phase, allowing the capacitor to store charge representative of a weighted input. By exchanging charge with other sense nodes during a compute phase, the resulting voltage can reflect the analog output of a MAC operation.

Some inventive concepts described herein relate to using the capacitor as a charge-based storage and accumulation element during computation. Unlike current-mode designs, this approach may enable MAC operations without relying on precise read currents or finely tuned conductance levels. Charge levels accumulated on capacitors can represent either binary or multi-bit weights, depending on how the nonvolatile memory transistor is programmed and how voltages are applied across the array. This configuration can simplify peripheral design and improve resilience to variability.

Some inventive concepts described herein relate to enabling support for MLC weight storage and computation in a charge-domain CiM architecture. In these examples, each nonvolatile memory transistor can be programmed to one of several threshold voltage states, with each state corresponding to a discrete weight level. A sequence of voltage pulses can be applied to selectively charge capacitors based on the stored state and applied input. The final charge sharing step among sense nodes can produce a voltage that corresponds to a dot-product output. In this way, multi-bit MAC operations can be performed using standard FeFET programming techniques.

Some inventive concepts described herein relate to variation tolerance in CiM systems. By using the FeFET as a switch rather than a programmable conductance element, the system may be less sensitive to variation in ON current or threshold voltage drift. Charge-based sensing can proceed based on whether a capacitor is charged, rather than requiring the precise measurement of small analog currents. In some examples, both cell-level and array-level experiments demonstrate consistent operation under threshold voltage variation and capacitor mismatch, suggesting that the architecture can remain robust under a range of practical conditions.

Some inventive concepts described herein relate to improvements in energy efficiency and area efficiency at the system level. The use of a compact 1FeFET1C cell structure may allow the design to leverage established DRAM layout principles, supporting high-density integration. Charge-domain computing can reduce static power consumption compared to current-mode designs, particularly in large arrays. Simulation and benchmarking results indicate that the disclosed architecture can outperform conventional CiM designs in both energy and area metrics, making it suitable for deployment in AI accelerators and related applications.

Some inventive concepts described herein provide an alternative CiM strategy that may reduce sensitivity to device-level variation, enable both binary and multi-bit MAC operations, and improve energy and area efficiency through the use of charge-based computation. These features may allow the disclosed architecture to be integrated into a wide range of memory-centric processing systems, offering a versatile platform for scalable, in-memory computing.

Some inventive concepts described herein relate to a CiM architecture is disclosed that supports binary and multi-level cell (MLC) operations using a charge-domain design incorporating FeFETs. The architecture can provide improved energy efficiency and robustness to device variation relative to current-domain CiM implementations. The functionality of the binary and MLC MAC operations can be demonstrated through both cell-level and array-level evaluations. In addition, macro-level benchmarking results indicate that the disclosed design can achieve higher area efficiency and energy efficiency compared to prior CiM approaches.

With the rapid advances in AI models, CiM architectures have been explored to address increasing computational demands. In this regard, both binary and MLC non-volatile memory (NVM) based CiM architectures can be attractive. Existing NVM-based CiM methodologies can be categorized into two main types: (i) current-domain CiM and (ii) charge-domain CiM.

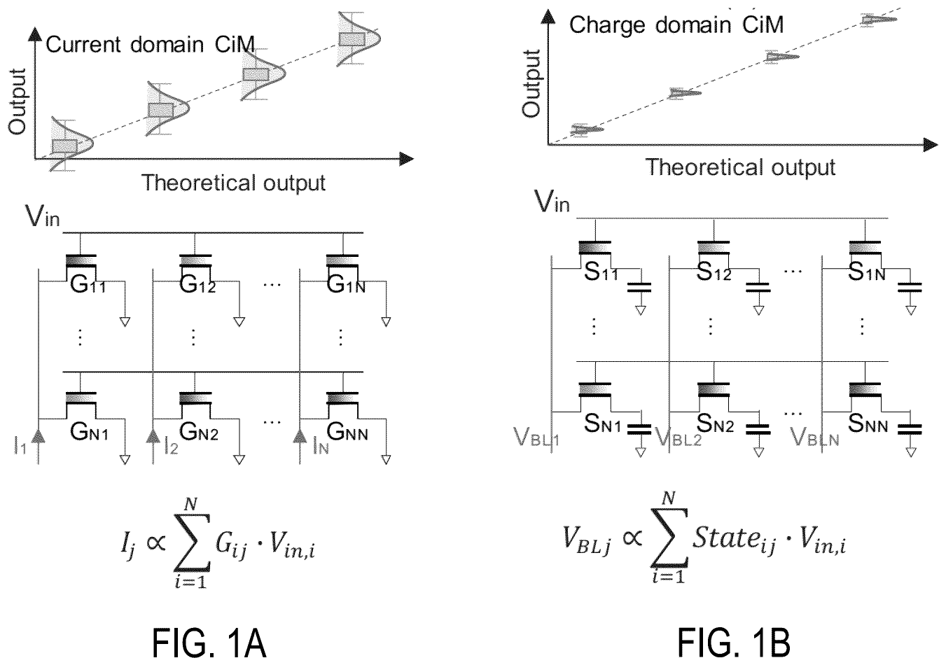

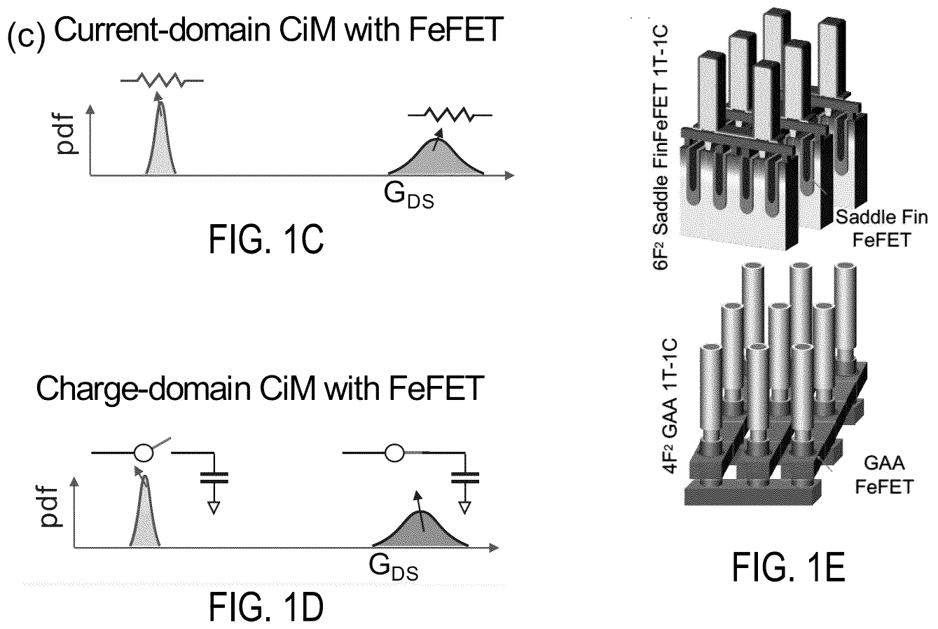

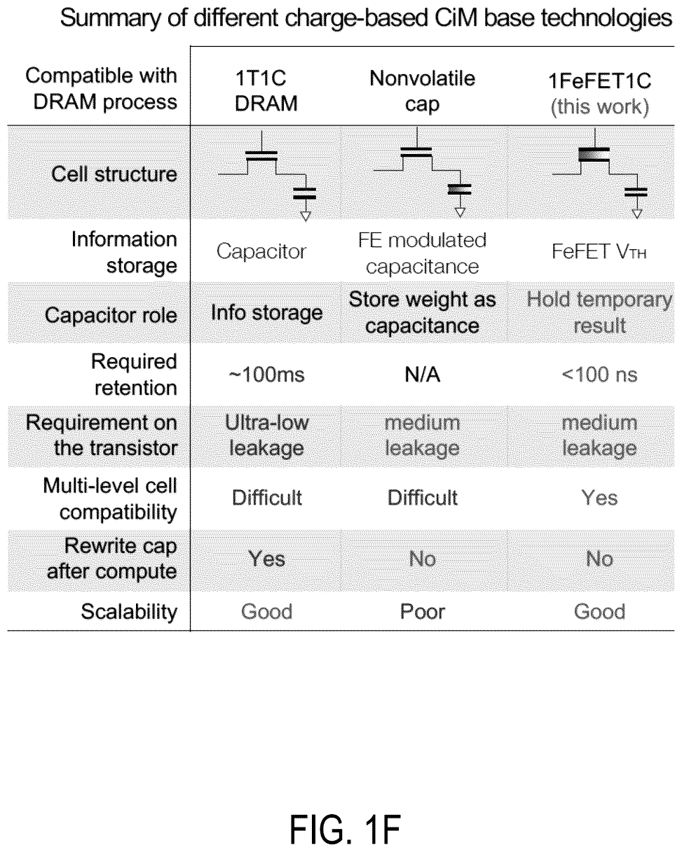

FIG. 1A illustrates an example of a current-domain CiM design in which NVM devices such as FeFETs are used as programmable conductance elements and computation is performed by summing currents from multiple cells. This configuration can involve sensitivity to the conductance values of the devices, which can impact the ability to distinguish different computation results.

FIG. 1B illustrates an example of a charge-domain CiM design in which FeFETs operate as switches and computation is performed by controlling the charging or discharging of capacitors. In these designs, the exact ON current may be less critical, so long as capacitors charge or discharge appropriately during operation.

FIG. 1C illustrates that current-domain CiM designs can face challenges in maintaining computational accuracy for both binary and MLC operations due to sensitivity to conductance variations.

FIG. 1D illustrates that in charge-domain CiM, FeFETs can function as switches, allowing computation without relying on precise ON current values.

FIG. 1E illustrates a 1FeFET-1C cell structure that resembles a DRAM cell and supports charge-domain CiM with both binary and MLC FeFETs. This structure can leverage established DRAM technology to enable high-density CiM arrays.

FIG. 1F illustrates that a 1FeFET1C-based charge-domain CiM design can provide relaxed requirements on capacitor retention and transistor leakage, as well as lower power consumption, MLC compatibility, and scalability, compared to other charge-domain CiM designs using different technologies.

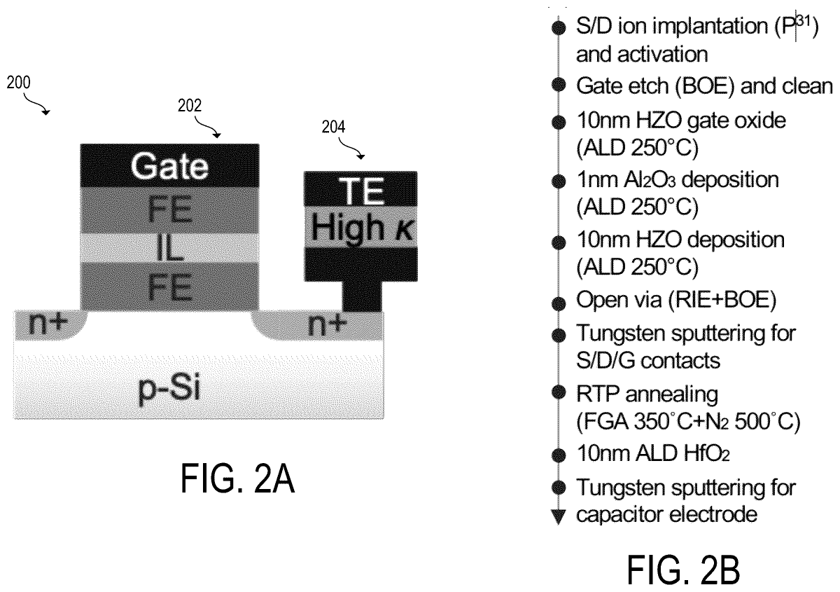

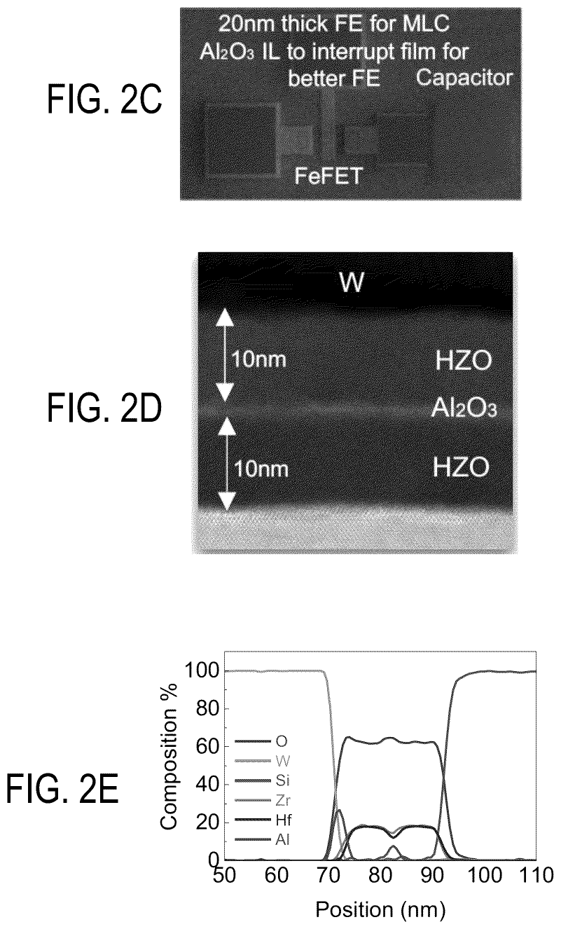

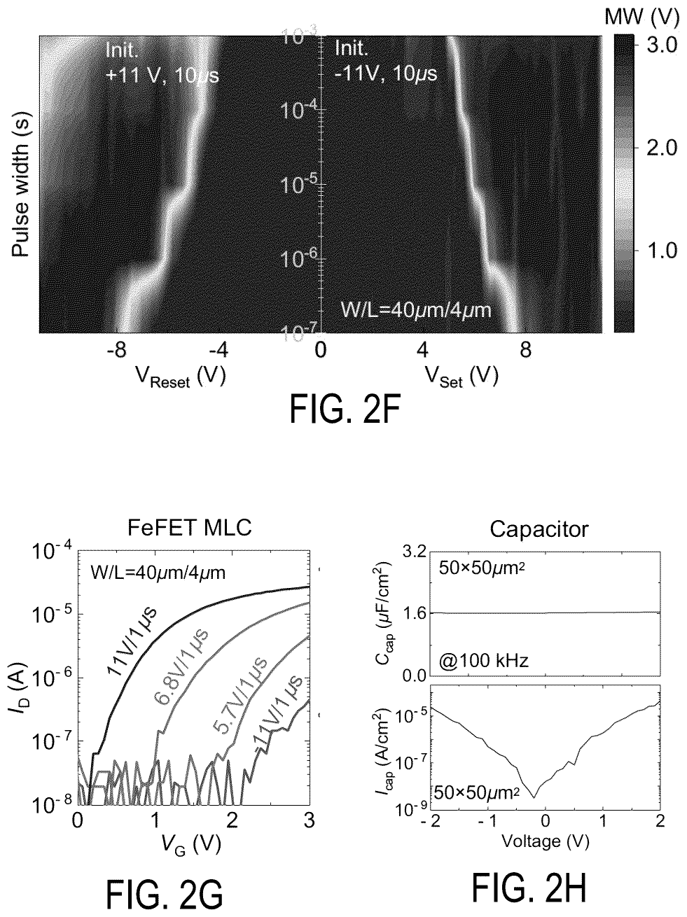

FIG. 2A illustrates an example of a CiM cell 200 that can implement various features corresponding to those described in one or more of the claims below. In this example, the CiM cell 200 can include a nonvolatile memory transistor 202 and a capacitor 204 electrically coupled in series between a bit line and a sense node. The nonvolatile memory transistor 202 includes a gate terminal, a first terminal, and a second terminal (e.g., source and drain regions) formed on a p-type silicon (p-Si) substrate. In some embodiments, as depicted here, the nonvolatile memory transistor can be a ferroelectric field-effect transistor (FeFET) having a gate stack that includes one or more ferroelectric dielectric layers, an interfacial layer, and a gate electrode. However, other nonvolatile transistor types (e.g., charge-trapping devices, resistive switching elements, or phase-change transistors) can be used so long as they are capable of retaining a programmable state and selectively conducting based on a control voltage applied to the gate terminal.

In operation, the transistor 202 can be programmed to a threshold voltage state (binary or multi-bit) corresponding to a weight value for in-memory computing tasks, such as multiply-accumulate (MAC) operations. During a charging phase, the bit line can be driven with an input voltage, while an appropriate control voltage is applied to the gate terminal. If the transistor 202 is in a conductive state (based on its programmed threshold), current can flow from the bit line through the transistor 202 to the capacitor 204. This allows the capacitor 204 to accumulate a corresponding level of electrical charge that encodes the product of the input and the weight. Depending on whether the transistor 202 is programmed to a “low-threshold” or “high-threshold” state (or, in multi-bit scenarios, one of several distinct levels), the capacitor 204 may store a nonzero charge or substantially no charge. In further examples, multiple partial charging steps—applied via a sequence of bit-line input voltages and gate control voltages—can be used to incrementally build up different charge levels on the capacitor 204 for multi-bit weight representation.

Once charging completes, the sense node is effectively storing charge representative of the programmed weight and the supplied input. In a subsequent compute phase, the bit line can be floated (or driven to a suitable reference potential), and the sense node can be electrically connected to other sense nodes in the same column, row, or both through shared lines or pass transistors. This configuration permits analog redistribution of charge among multiple capacitors in the array. As a result, the voltage at each sense node can reflect the cumulative charge contributions from all contributing CiM cells, thereby representing an analog MAC output. Notably, because the FeFET (or other nonvolatile device) simply functions as an on/off (or partially on) switch during the charging phase, the actual conduction current is less critical than in current-domain CiM designs. Instead, the emphasis is on whether the capacitor 204 accumulates the intended amount of charge based on the transistor's programmable threshold state.

In some embodiments, the capacitor 204 can be discharged to a baseline voltage prior to each charging cycle to ensure accurate accumulation of new charge. This discharge step can be facilitated by dedicated circuitry or by driving the bit line and sense node to a known voltage level while the transistor 202 is turned on. Furthermore, the sense node can interface with peripheral circuits such as sense amplifiers or analog-to-digital converters to convert the final analog voltage to a digital signal that corresponds to the MAC computation result. By leveraging a nonvolatile transistor 202, the cell 200 can retain its programmed weight state without requiring periodic refresh, and charge-based operations can proceed without destructively reading or altering that stored state.

Although FIG. 2A shows a single CiM cell 200 in a 1FeFET1C configuration, it will be understood that a typical compute-in-memory array includes many such cells arranged in rows and columns. Each cell can be coupled to a common word line at its gate terminal and to shared bit lines and sense nodes. During MAC operations, control voltages applied to the WLs selectively activate the nonvolatile transistors according to stored threshold voltages, while the BLs supply input signals. The resulting charge on each capacitor 204 can then be redistributed among sense nodes to produce an analog sum of weighted inputs across multiple cells. Such an architecture can be scaled for various analog computing tasks, offering robust tolerance to device-level variations and reduced energy consumption compared to traditional current-domain or digital von Neumann approaches.

FIG. 2B illustrates an example process flow for fabricating the CiM cell of FIG. 2A. In this example, fabrication begins with source/drain ion implantation using phosphorus-31 (P³¹), followed by thermal activation. A gate etch and clean step (e.g., using buffered oxide etch (BOE)) can be performed. A ferroelectric gate stack can be formed by sequentially depositing a 10 nm layer of hafnium zirconium oxide (Hf_{0.5}Zr_{0.5}O₂), a 1 nm layer of aluminum oxide (Al₂O₃), and another 10 nm layer of Hf_{0.5}Zr_{0.5}O₂ using atomic layer deposition (ALD) at approximately 250° C.

A via can be opened using a combination of reactive ion etching (RIE) and BOE. Tungsten (W) sputtering can be performed to form source, drain, and gate contacts. The device can then undergo rapid thermal annealing (RTP) at, for example, 350° C. in forming gas (FGA) and 500° C. in nitrogen (N₂) atmosphere.

To form the capacitor, a 10 nm layer of hafnium oxide (HfO2) can be deposited using ALD, followed by tungsten (W) sputtering to define the capacitor's top electrode. The bottom electrode of the capacitor can also be formed using tungsten sputtering during an earlier stage.

It will be appreciated that the specific materials, thicknesses, and process conditions described in this example can be varied. For instance, different high-k dielectric materials, ferroelectric materials, or metal electrodes can be used; deposition techniques other than ALD may be employed; and annealing conditions can be adjusted to accommodate alternative integration schemes or target device performance.

FIG. 2C illustrates an example top-view scanning electron microscopy (SEM) image of a fabricated CiM cell, such as the cell shown in FIG. 2A, including a FeFET and a capacitor. The image shows the relative physical layout of the FeFET and the capacitor, where the capacitor is positioned adjacent to the FeFET to enable compact integration of the 1FeFET1C structure. The ferroelectric layer in this example is approximately 20 nm thick, and an intermediate Al₂O₃ layer can be included to enhance ferroelectric behavior.

FIG. 2D illustrates an example cross-sectional transmission electron microscopy (TEM) image of the FeFET gate stack in the CiM cell of FIG. 2A. The image shows two 10 nm layers of Hf_{0.5}Zr_{0.5}O₂ (HZO) separated by a 1 nm interlayer (IL) of Al₂O₃, formed over a p-Si substrate with n⁺ source/drain regions. A tungsten (W) gate electrode is formed above the gate stack.

FIG. 2E illustrates an example elemental composition profile measured across the gate stack of the FeFET in the CiM cell of FIG. 2A. The elemental distribution shows spatially resolved concentrations of Hf, Zr, Al, O, and other elements across the gate stack. The Al₂O₃ interlayer is located between the two HZO layers and can serve to inhibit crystallization into an undesired monoclinic phase, thereby preserving ferroelectricity.

FIG. 2F illustrates example memory window characteristics for the FeFET of FIG. 2A under positive and negative programming voltages. The figure shows a memory window (MW) of approximately 2.5 V, with programming dynamics under different pulse widths and voltages. The programmable window can support multi-level threshold voltage states for MLC functionality.

FIG. 2G illustrates example current-voltage characteristics (I_D-V_G) for the FeFET in the CiM cell of FIG. 2A, showing four distinct threshold voltage states suitable for multi-level cell operation. In this example, the FeFET has a channel width-to-length ratio of 40 μm/4 μm, and programming is performed with pulse conditions such as 11 V/1μs, 6.8 V/1μs, and 5.7 V/1μs. The four V_{T} states demonstrate suitability for analog or MLC computation.

FIG. 2H illustrates example measured capacitance and leakage current characteristics of the capacitor in the 1FeFET1C cell of FIG. 2A. The measurements are taken from a 50 μm ×50 μm capacitor structure at 100 kHz. The top panel shows a flat capacitance profile across a range of voltages, and the bottom panel shows the leakage current density as a function of voltage, both of which indicate compatibility with CiM operation.

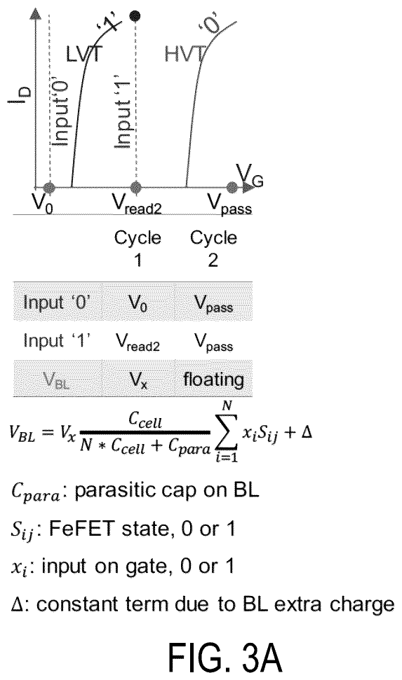

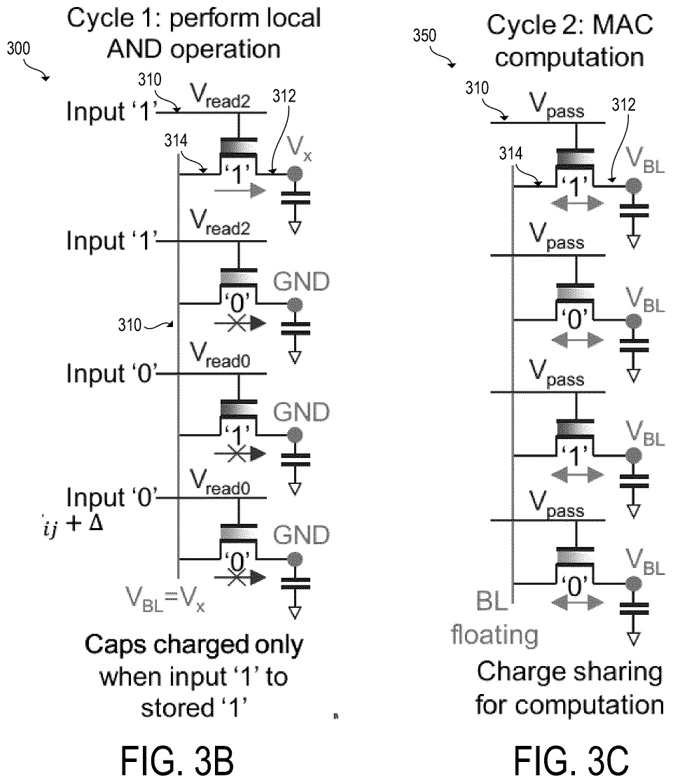

FIGS. 3A-3C illustrate principles of an example of binary CiM operation using a 1FeFET1C cell array 300. In each cell, a weight bit can be stored by setting the FeFET to either a low-threshold voltage (LVT) state or a high-threshold voltage (HVT) state. During a first operation cycle, bit lines 310 can be biased to a voltage Vx, and inputs can be applied to word lines 312, controlling the charging of the cell capacitors according to the logic AND between input and stored weight. In a second cycle, a pass voltage Vpass can be applied to the WLs while the BLs are floated, enabling charge redistribution and resulting in a cumulative MAC output.

FIG. 3B illustrates an example circuit-level schematic 300 representing Cycle 1 of a binary CiM operation, while FIG. 3C illustrates an example circuit-level schematic 350 representing Cycle 2. In these figures, each cell is depicted with a gate terminal 310 (coupled to a word line, WL), a first terminal 312 (coupled to a bit line, BL), and a second terminal 314 (coupled to the capacitor and ultimately a sense node, SN). During Cycle 1, the bit line (connected to first terminal 312) is driven with an input voltage (Vₓ), and the gate terminal 310 receives read/control voltages (e.g., Vread0, Vread2) via the word line. The nonvolatile memory transistor in each cell conducts and charges the capacitor only if the stored threshold voltage corresponds to a “1” and the input is also “1.” Cells storing a “0” or receiving a “0” input remain uncharged.

During Cycle 2, as shown in FIG. 3C, the bit line is floated, and a pass voltage (Vpass) is applied to the gate terminal 310 (or a corresponding select line) to enable charge sharing among the sense nodes connected to second terminal 314. By combining or redistributing charge from multiple capacitors, the final voltage at each sense node reflects the sum of stored weight values multiplied by the corresponding inputs, thereby completing the multiply-accumulate operation. This two-cycle approach—local charging followed by global redistribution—is characteristic of binary CiM designs, but can be extended to multi-bit implementations by incorporating additional partial charging steps or expanded control voltage sequences, as described elsewhere.

FIG. 3C illustrates an example schematic of the array-level binary CiM operation for four different cells. Capacitor charging occurs only when both the input is ‘1’ and the weight is stored as a low-VTH state, such that the FeFET is turned on during Cycle 1. During Cycle 2, bit lines are floated and charge is redistributed across the array to generate an analog voltage representing the MAC result.

In an example equation for calculating the resulting bit line voltage, the voltage VBL is a function of the input vector and the stored FeFET states, the total number of cells, and contributions from cell and parasitic capacitances, with an optional correction term Δ to account for excess charge on the bit line.

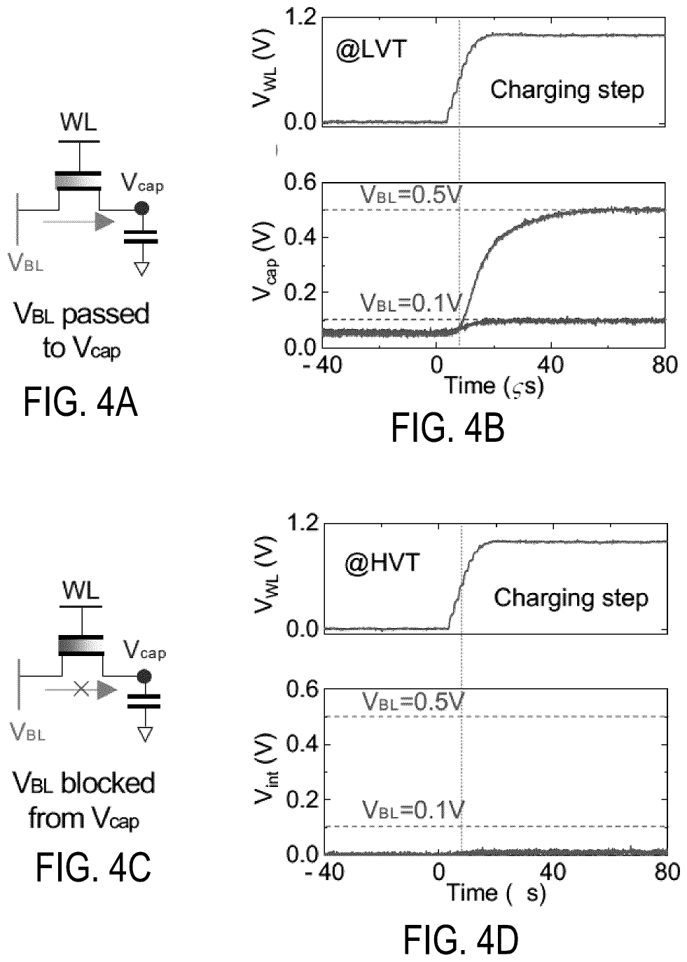

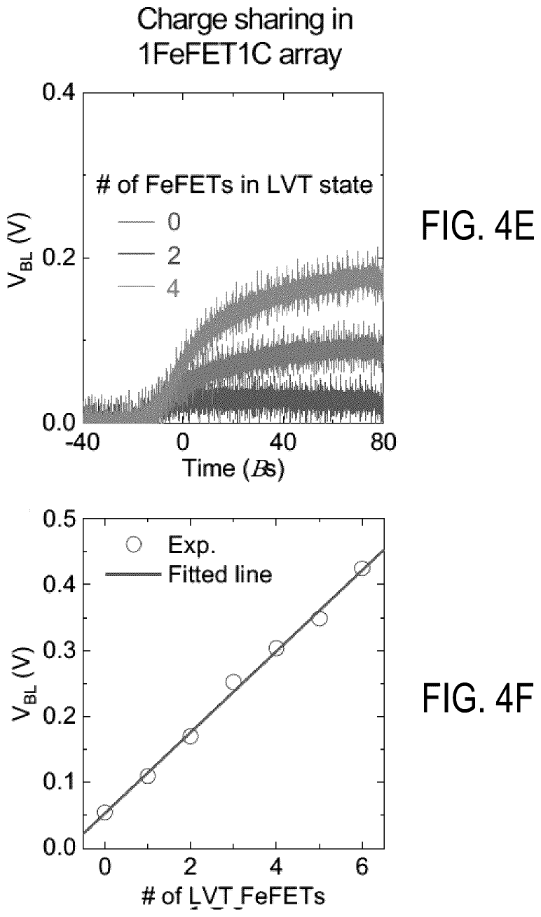

FIG. 4A illustrates an example CiM cell having the FeFET programmed to a low-threshold voltage (LVT) state, enabling conduction between the terminals. In this condition, the bit line voltage VBL can be passed to the cell capacitor Vcap during the charging step.

FIG. 4B illustrates an example waveform confirming that capacitor charging can occur when the FeFET is in the LVT state. As shown, the applied word line (WL) and bit line (VBL) voltages result in a corresponding increase in Vcap over time.

FIG. 4C illustrates an example CiM cell in which the FeFET is programmed to a high-threshold voltage (HVT) state, inhibiting conduction. In this case, the FeFET remains off during the charging step, and no charge transfer to the capacitor occurs.

FIG. 4D illustrates an example waveform showing suppression of capacitor charging when the FeFET is in the HVT state. Even though WL and VBL voltages are applied, the capacitor voltage remains near baseline, indicating that charge flow is blocked.

FIG. 4E illustrates example transient behavior of the bit line during charge sharing in a 1FeFET1C array. The bit line voltage VBL increases proportionally based on the number of cells in the LVT state that contribute charge, as shown for different numbers of activated cells.

FIG. 4F illustrates an example linear relationship between the number of FeFETs in the LVT state and the resulting bit line voltage. The measured VBL shows good agreement with a fitted line, confirming analog accumulation across the array.

Multiple sensing techniques may be utilized in MLC non-volatile memory (NVM)-based CiM systems. One sensing technique may include parallel sensing, in which a constant and sufficiently high gate voltage (VG) is applied to distinguish memory states based on current values.

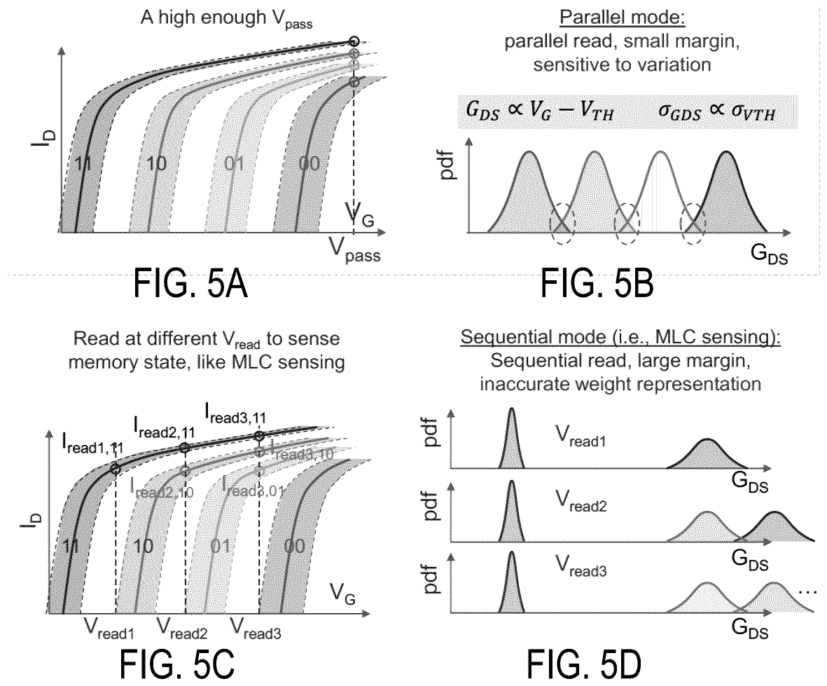

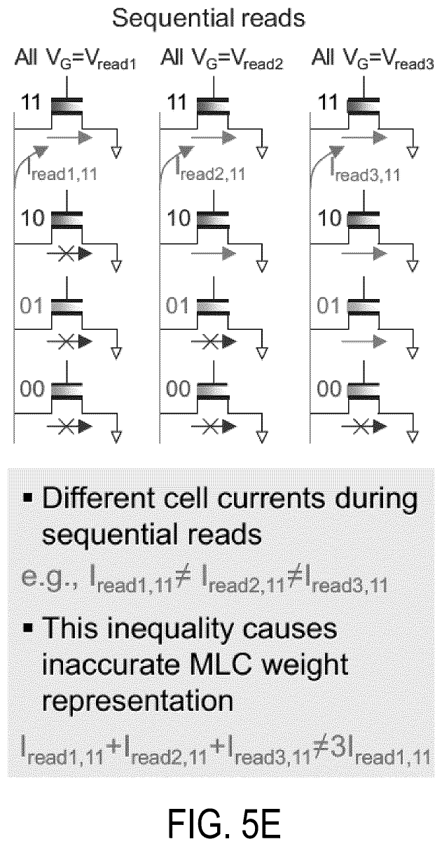

FIG. 5A illustrates an example of parallel sensing mode in which a constant VG is applied and the output drain current (ID) is measured to identify different MLC states. In this example, higher conductance corresponds to lower threshold voltage states.

FIG. 5B illustrates an example of the probability density function (pdf) of sensed current values for parallel sensing. The distribution overlap indicates a relatively narrow sense margin, which can lead to increased sensitivity to threshold voltage variation and reduced state distinguishability.

A second sensing technique may include sequential sensing, where multiple read voltages are applied over successive cycles, and the memory state is determined based on current values measured during each read step.

FIG. 5C illustrates an example of sequential sensing mode using multiple VG levels (e.g., Vread1, Vread2, Vread3) to selectively activate cells with different MLC states.

FIG. 5D illustrates an example of the sensed current distributions for the sequential sensing method. This example shows a larger separation between distributions, indicating that sequential sensing can offer improved sense margins compared to parallel sensing.

However, sequential sensing in current-domain NVM CiM may still be subject to errors caused by variations in the current response at different read steps, potentially leading to inaccurate weight representation.

FIG. 5E illustrates an example challenge in current-domain CiM using sequential sensing. In this example, different cell currents observed at each read voltage (e.g., Iread1,11, Iread2,11, Iread3,11) are not equal, which can result in incorrect decoding of multi-bit weights. A visual representation is provided showing how unequal contributions from individual reads can cause misrepresentation of intended weight values.

To address this challenge, a 1FeFET1C cell architecture supporting charge-domain operation may be employed. In this design, FeFETs can function as nonvolatile switches that control whether associated capacitors are charged. Computation results can be stored as charge on capacitors, thereby removing the need for precise current-based readout.

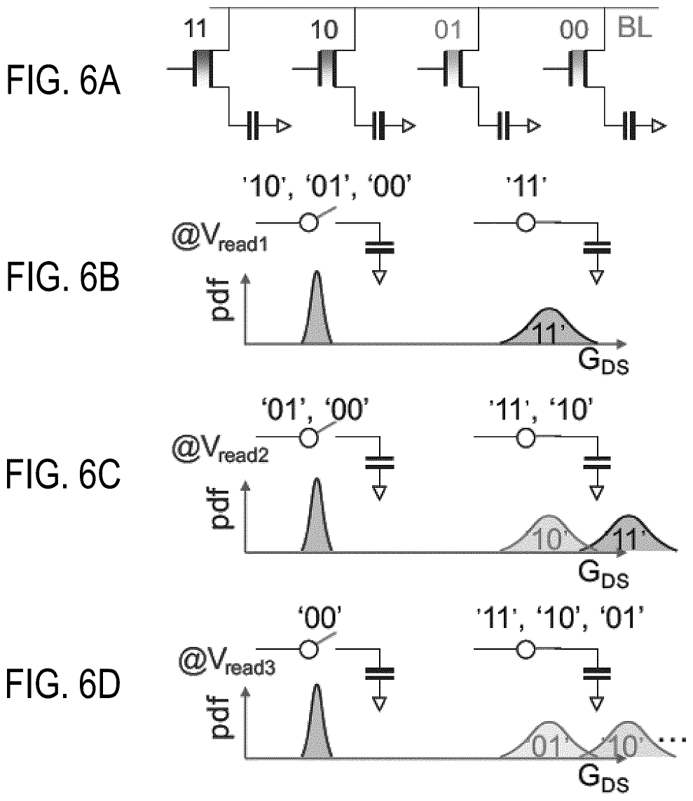

FIG. 6A illustrates an example configuration of a charge-domain CiM array that includes multiple 1FeFET1C cells, each configured to store a 2-bit MLC weight. In this configuration, each FeFET may operate as a nonvolatile switch, and memory states (e.g., ‘11’, ‘10’, ‘01’, ‘00’) may be used to selectively enable charging behavior across different word line (WL) and bit line (BL) voltages.

FIG. 6B illustrates an example charge-domain sensing condition for an applied word line voltage Vread1. Under this condition, cells programmed to the ‘11’ state may conduct and transfer charge, while other states (‘10’, ‘01’, ‘00’) may remain non-conductive. The corresponding probability density function (pdf) of GDS indicates separation between conductive and non-conductive states.

FIG. 6C illustrates an example sensing behavior at a second voltage level Vread2. At this level, cells in the ‘10’ state may become conductive, while those in ‘01’ and ‘00’ states may continue to remain non-conductive. The illustrated GDS distribution reflects this selective activation.

FIG. 6D illustrates a third example sensing step using a read voltage Vread3. At this voltage, cells programmed to the ‘01’ state may conduct, while cells in the ‘00’ state may remain non-conductive.

Collectively, the configurations and waveforms shown in FIG. 6A-6D demonstrate how a charge-domain CiM array incorporating 1FeFET1C cells can support MLC sensing operations through voltage-controlled switching behavior. Because the FeFETs act as switches, rather than variable conductance elements, precise read currents may not be necessary, allowing for enhanced tolerance to variation in device characteristics.

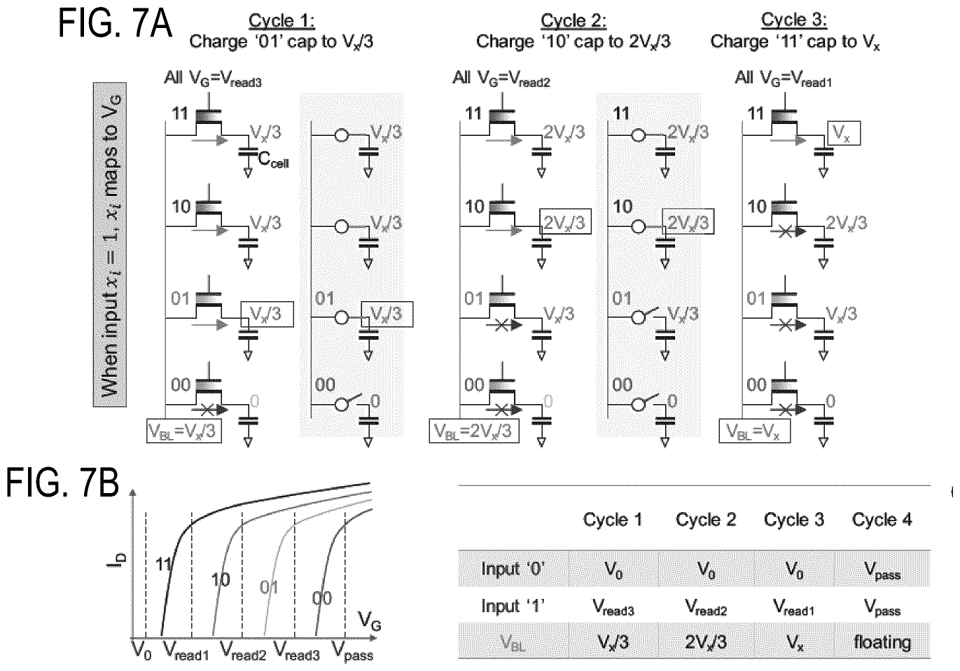

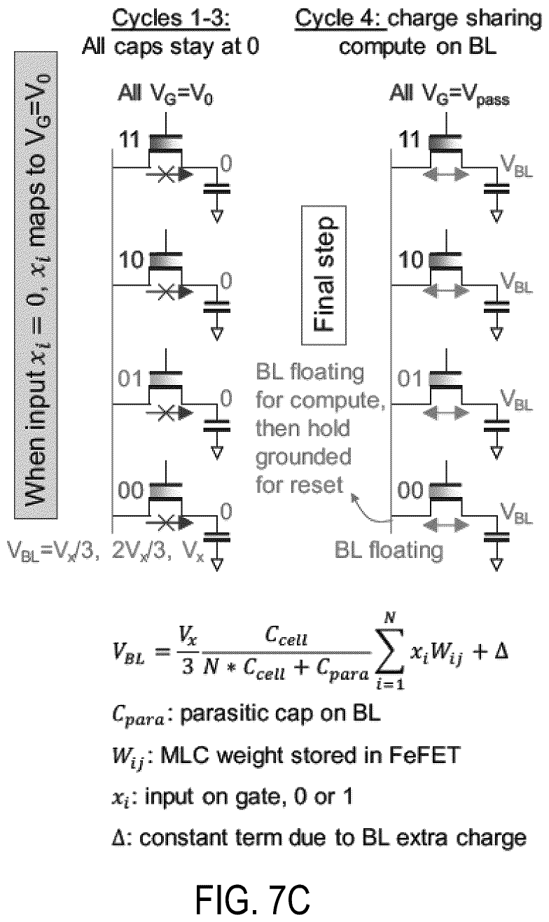

FIG. 7A illustrates an example four-cycle charge-domain operation using 1FeFET1C cells. During the first three cycles, word lines (WLs) can receive gate voltages Vread3, Vread2, and Vread1, respectively, to control FeFET conduction depending on the programmed MLC state. At the same time, different voltages can be applied to the bit lines (BLs)—namely Vx/3, 2Vx/3, and Vx—to charge capacitors according to the effective product of input and stored weight. In the final (fourth) cycle, a pass voltage Vpass can be applied to the WLs, and BLs can be floated, allowing charge redistribution across cells in the same column. This redistribution may generate an analog output corresponding to a MAC result.

FIG. 7B illustrates an example set of FeFET transfer characteristics as a function of gate voltage VG. These curves can represent threshold voltage separation for the different MLC states (‘00’, ‘01’, ‘10’, ‘11’), which in turn enables voltage-selective control of conduction for charge-domain sensing operations.

FIG. 7C illustrates a summary of voltages applied during each operation cycle. As shown, the WL voltage is selected based on the input bit, and BL voltage is selected based on the intended capacitor charging level. The compute cycle involves floating the BLs to allow charge sharing, which can result in a final bit line voltage (VBL) that reflects the accumulated analog result of a dot-product computation. The equation provided summarizes how VBL can depend on the sum of the products of binary input bits and stored MLC weights.

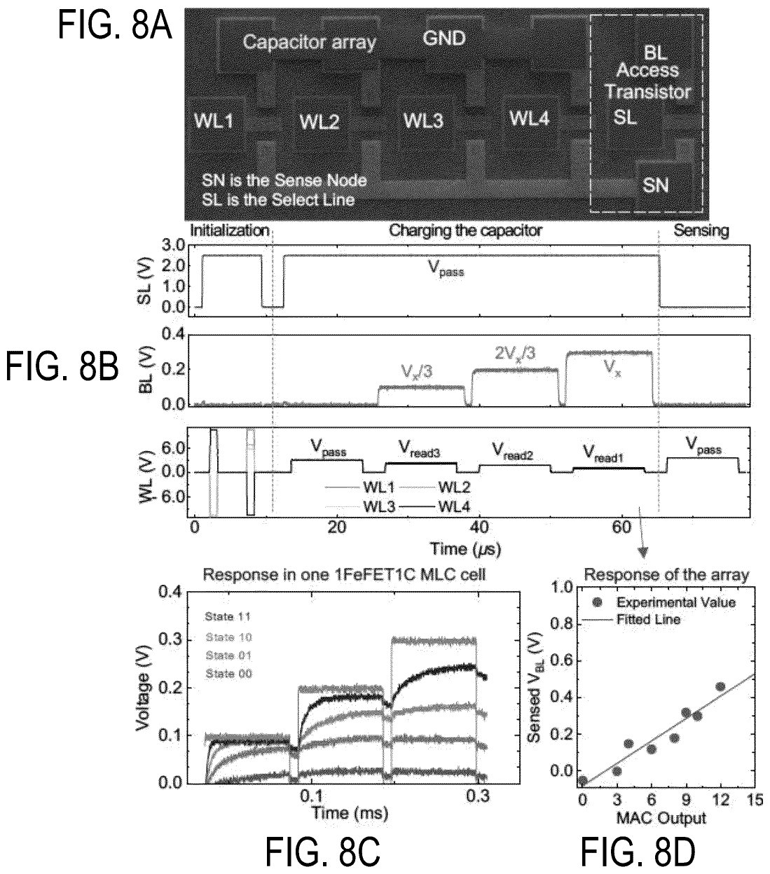

FIG. 8A illustrates an example top view scanning electron microscope (SEM) image of a fabricated 1FeFET1C CiM array. In this example, the array includes word lines (WL1-WL4), a bit line (BL), a select line (SL), and a sense node (SN). For demonstration purposes, an access transistor is included in each cell. The gate of the access transistor is controlled by the SL, and can be biased to connect or disconnect the BL from the floating SN, which can enable or isolate the cell during charging and charge-sharing operations.

FIG. 8B illustrates example timing waveforms associated with the charge-domain MLC CiM operation. The sequence includes initialization, charging, and sensing phases. In the initialization phase, capacitors in all cells are discharged to ground. During the charging phase, WLs are biased sequentially with read voltages Vread3, Vread2, and Vread1 to control FeFET conduction. Simultaneously, BLs are driven with Vx/3, 2Vx/3, and Vx to incrementally charge the capacitors based on the MLC state of the associated FeFET. In this example, Vx is set to 0.3 V, and the read voltages are chosen as Vread3=2.1 V, Vread2=1.6 V, and Vread1=0.9 V, based on the threshold voltages of the FeFETs in different MLC states. In the final sensing phase, Vpass is applied and the SL is deactivated to allow charge sharing.

FIG. 8C illustrates example transient voltage waveforms of a single 1FeFET1C cell during the charging process for different MLC states. The capacitor voltage increases in discrete steps based on the programmed threshold voltage of the FeFET. Four distinguishable voltage levels are observed, corresponding to the four possible MLC states (‘00’, ‘01’, ‘10’, ‘11’). After charging is complete, the access transistor is turned OFF, floating the SN and preparing the cell for charge redistribution.

FIG. 8D illustrates an example of sensed voltage at the SN during the compute phase following charge sharing among four cells. The sensed voltage demonstrates a substantially linear relationship with respect to the expected MAC output. This behavior confirms that analog accumulation is performed successfully, validating the charge-domain MLC operation using the fabricated 1FeFET1C array.

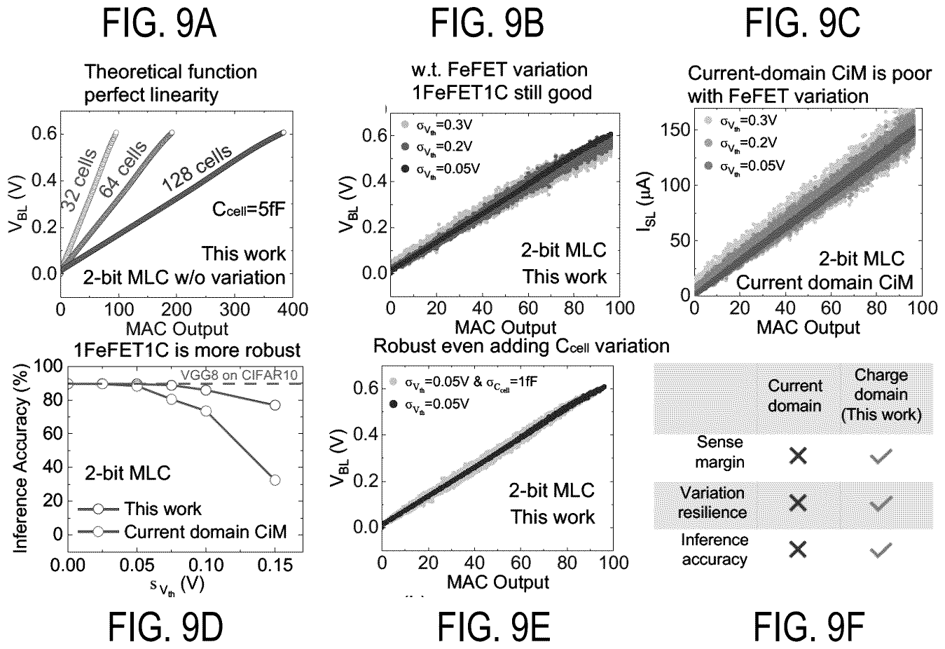

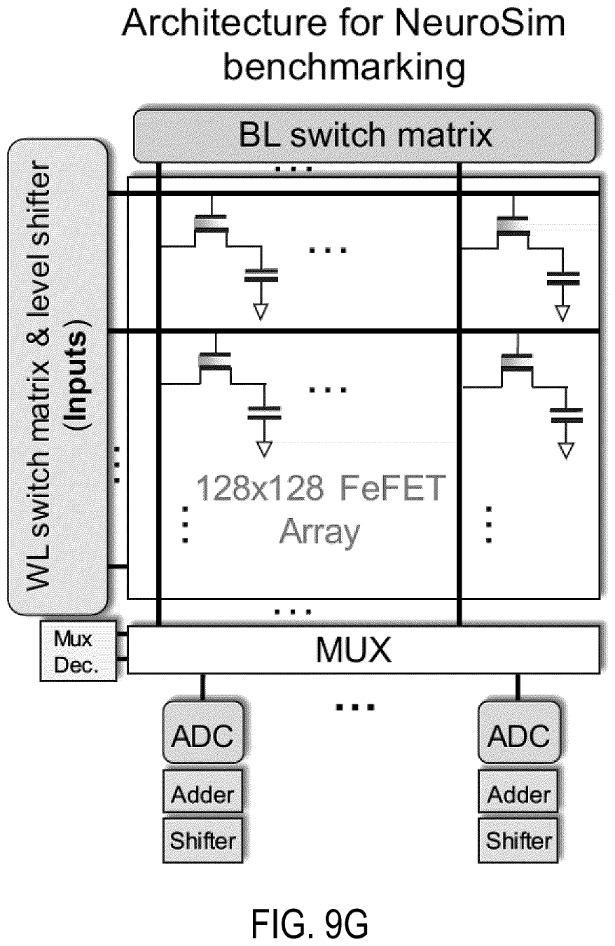

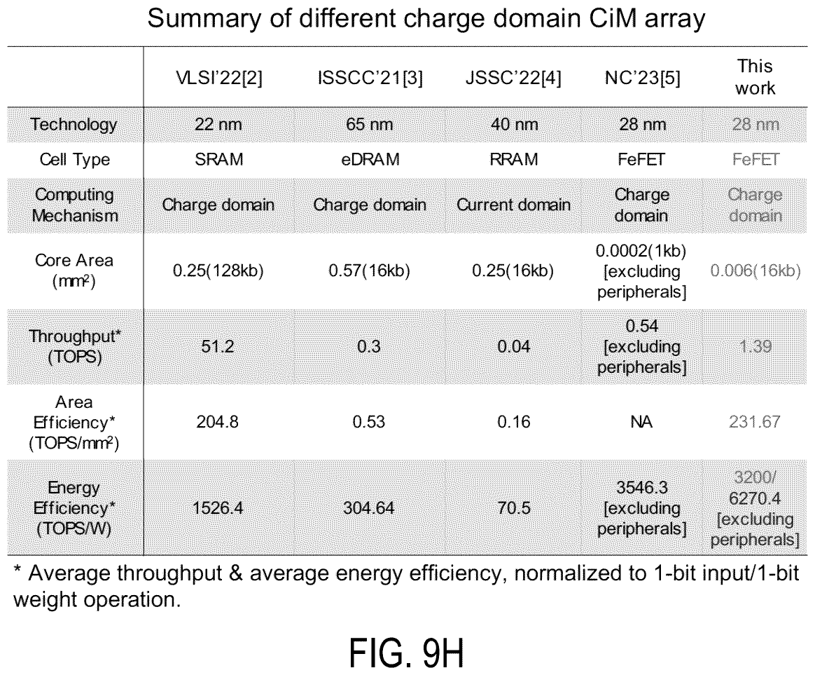

FIG. 9A illustrates an example of VBL behavior as a function of MAC output for an array of 1FeFET1C cells. In this example, simulation results are shown for 32, 64, and 128 cells in a column without device variation. The results demonstrate a high degree of linearity between VBL and MAC output, with a capacitance of approximately 55 fF used for each cell. These results indicate the suitability of the architecture for scaled systems.

FIG. 9B illustrates an example Monte Carlo simulation result modeling the effect of threshold voltage (VTH) variation in the 1FeFET1C charge-domain CiM array. Even with up to ±4σ variation in VTH (0.3 V, 0.2 V, and 0.05 V cases shown), the VBL output remains substantially linear, highlighting the tolerance of the design to threshold variation.

FIG. 9C illustrates an example of current-domain CiM behavior under the same VTH variation. The data shows significantly higher spread and nonlinearity in output current compared to the charge-domain implementation, demonstrating reduced robustness in the current-domain design.

FIG. 9D illustrates an example of inference accuracy under varying VTH conditions. In this example, the charge-domain 1FeFET1C array is compared with a current-domain CiM design using a 2-bit MLC implementation. Accuracy is evaluated using the CIFAR-10 dataset and a VGG8 model. The charge-domain array retains inference accuracy with increasing VTH variation, while the current-domain alternative shows a larger degradation.

FIG. 9E illustrates an example of output voltage variation when both VTH and cell capacitor (Ccell) variation are introduced. Even under simultaneous variation, the output voltage (VBL) remains substantially linear with MAC output, further demonstrating robustness to combined device-level variability.

FIG. 9F illustrates a comparison of architectural characteristics between charge-domain and current-domain CiM systems. The figure highlights relative differences in sense margin, variation resilience, and inference accuracy. The charge-domain approach demonstrates advantages across all three categories.

FIG. 9G illustrates an example configuration of a 128×128 1FeFET1C array and associated peripheral circuits used for benchmarking. This configuration includes a bit line (BL) switch matrix, multiplexer (MUX), and analog-to-digital converter (ADC), integrated with the array for system-level evaluation.

FIG. 9H illustrates a benchmarking comparison between a 1FeFET1C charge-domain array and other previously reported charge-domain CiM systems. Evaluation is conducted using the DNN+NeuroSim framework with 8-bit input activations and 8-bit weights using the VGG8 model on the CIFAR-10 dataset. The 1FeFET1C design achieves an energy efficiency of 3200 TOPS/W and area efficiency of 231.67 TOPS/mm² with 1-bit input and 1-bit weight, outperforming prior systems in both metrics.

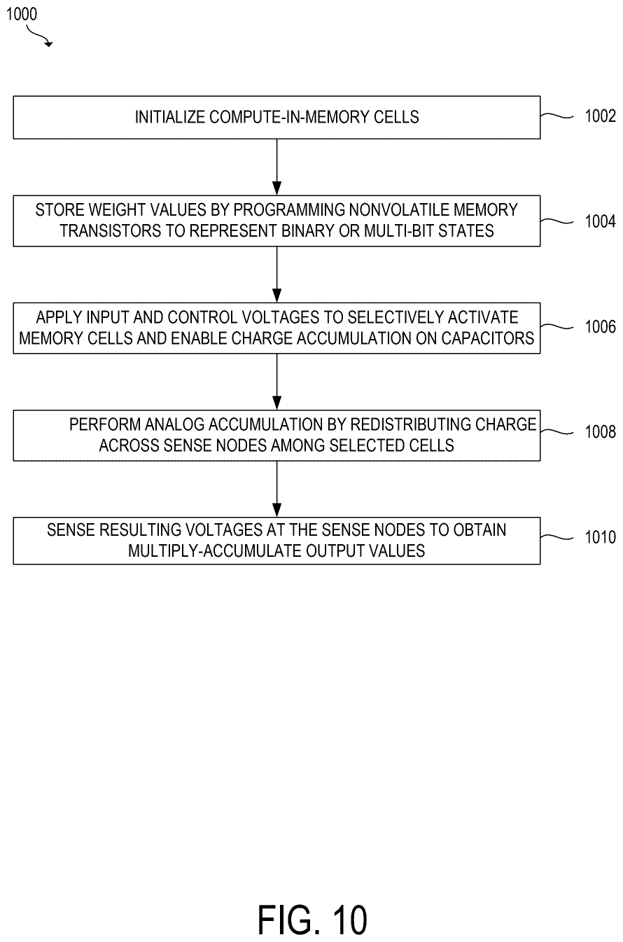

FIG. 10 illustrates a flow diagram illustrating an embodiment of routine 1000, which can be implemented by a CiM system that includes one or more CiM cells, each having a nonvolatile memory transistor (e.g., a ferroelectric transistor or another suitable nonvolatile transistor technology) in series with a capacitor. The diagram outlines an example process by which the system can initialize CiM cells, program the nonvolatile memory transistors to store either binary or multi-bit weight values, apply input and control voltages to selectively activate memory cells for charge accumulation, perform analog accumulation via charge redistribution, and sense the resulting voltages to obtain MAC outputs. Although shown in a particular sequence, additional steps or variations can be included without departing from the scope of the inventive concepts described herein. Thus, the following illustrative embodiment should not be construed as limiting.

At block 1002, the CiM cells can be initialized. In some examples, this can include discharging the capacitors in each cell to a baseline voltage so that any residual charges from prior operations are removed. Additionally, initialization can include configuring peripheral circuitry (e.g., bit line drivers, word line drivers, or sense amplifiers) and/or control logic (e.g., a controller or sequencer) to manage the forthcoming operations. Depending on the design, this may include setting up any select lines or pass transistors that control access between each capacitor and the respective bit line or sense node.

At block 1004, weight values are stored by programming the nonvolatile memory transistors in each CiM cell to represent binary or multi-bit states. In some embodiments, the transistors can be FeFETs programmed to different threshold voltage levels. In some embodiments, other nonvolatile devices can be used, for example if they can be programmed to multiple states. This step may effectively embed a desired set of weights (e.g., from a neural network layer) into the CiM array. Because the devices are nonvolatile, these states can remain stable for extended periods without requiring refresh, supporting fast and energy-efficient MAC operations directly in the memory array.

At block 1006, the system applies input and control voltages to selectively activate memory cells and enable charge accumulation on the capacitors. As an example, bit lines may be driven with voltage pulses corresponding to input signals, while word lines (or gate terminals) receive control voltages that turn on (or keep off) the nonvolatile memory transistors based on their programmed threshold states. If a particular transistor is set to a low-threshold-voltage state and receives the appropriate input, it can conduct and allow charge to flow onto the capacitor. Conversely, a high-threshold-voltage state can block the path, preventing charging of the capacitor. In some multi-bit embodiments, multiple voltage levels and multiple partial charging steps can be employed to accumulate discrete charge levels that correspond to the multi-bit weight.

At block 1008, analog accumulation can be performed by redistributing charge across sense nodes among selected cells. In certain embodiments, the bit lines may be floated, and a pass voltage is applied to the word lines or select lines, allowing multiple capacitors to share or combine charge. This charge-domain summation can reflect the cumulative effect of the various inputs and the stored weight values, enabling an analog multiply-accumulate operation. Because the analog output arises from charge stored on capacitors, the sensitivity to small variations in transistor current may be reduced. In this case, a consideration may be whether the transistor allows charge transfer, rather than the precise current flow.

At block 1010, the resulting voltages at the sense nodes are sensed to obtain multiply-accumulate output values. Peripheral circuits, such as sense amplifiers, sample-and-hold elements, or analog-to-digital converters (ADCs), can measure each sense node voltage and convert it into a digital representation of the MAC result. In some designs, the sensing may be performed immediately after charge sharing. In others, the system may retain the accumulated charge on the sense nodes for a short period before performing analog-to-digital conversion. Depending on the application, the system can then forward these digital results to additional processing units or combine them with other computational stages within a larger AI or signal processing pipeline.

It will be understood that fewer, more, or different blocks can be used as part of routine 1000 of FIG. 10. For example, the routine 1000 can incorporate verification steps (e.g., reading back the programmed threshold voltages) before applying input signals, or additional charge-sharing cycles to refine the summation in certain high-precision computations. In some cases, the capacitors can be discharged and recharged multiple times if multi-phase accumulate operations are needed. Moreover, although the above focuses on an example 1FeFET1C configuration, other cell structures that use nonvolatile transistors for weight storage in combination with capacitors are also contemplated. Thus, the approach described herein can support a wide range of CiM architectures and remains adaptable to evolving device technologies and system-level requirements.

### Terminology

Although this disclosure has been described in the context of certain embodiments and examples, it will be understood by those skilled in the art that the disclosure extends beyond the specifically disclosed embodiments to other alternative embodiments and/or uses and obvious modifications and equivalents thereof. In addition, while several variations of the embodiments of the disclosure have been shown and described in detail, other modifications, which are within the scope of this disclosure, will be readily apparent to those of skill in the art. It is also contemplated that various combinations or sub-combinations of the specific features and aspects of the embodiments may be made and still fall within the scope of the disclosure. For example, features described above in connection with one embodiment can be used with a different embodiment described herein and the combination still fall within the scope of the disclosure. It should be understood that various features and aspects of the disclosed embodiments can be combined with, or substituted for, one another in order to form varying modes of the embodiments of the disclosure. Thus, it is intended that the scope of the disclosure herein should not be limited by the particular embodiments described above. Accordingly, unless otherwise stated, or unless clearly incompatible, each embodiment of this invention may include, additional to its essential features described herein, one or more features as described herein from each other embodiment of the invention disclosed herein.

The terminology used in the description of the inventive concept herein is for the purpose of describing particular embodiments only and is not intended to be limiting of the inventive concept. As used in the description of the inventive concept and the appended claims, the singular forms “a”, “an” and “the” are intended to include the plural forms as well, unless the context clearly indicates otherwise. Additionally, as used herein, the term “and/or” includes any and all combinations of one or more of the associated listed items and may be abbreviated as “/”.

The term “comprise,” as used herein, in addition to its regular meaning, may also include, and, in some embodiments, may specifically refer to the expressions “consist essentially of” and/or “consist of. ” Thus, the expression “comprise” can also refer to, in some embodiments, the specifically listed elements of that which is claimed and does not include further elements, as well as embodiments in which the specifically listed elements of that which is claimed may and/or does encompass further elements, or embodiments in which the specifically listed elements of that which is claimed may encompass further elements that do not materially affect the basic and novel characteristic(s) of that which is claimed. For example, that which is claimed, such as a composition, formulation, method, system, etc. “comprising” listed elements also encompasses, for example, a composition, formulation, method, system, etc. “consisting of,” i.e., wherein that which is claimed does not include further elements, and a composition, formulation, method, system, etc. “consisting essentially of,” i.e., wherein that which is claimed may include further elements that do not materially affect the basic and novel characteristic(s) of that which is claimed.

The term “about” generally refers to a range of numeric values that one of skill in the art would consider equivalent to the recited numeric value or having the same function or result. For example, “about” may refer to a range that is within ±1%, ±2%, ±5%, ±7%, ±10%, ±15%, or even ±20% of the indicated value, depending upon the numeric values that one of skill in the art would consider equivalent to the recited numeric value or having the same function or result. Furthermore, in some embodiments, a numeric value modified by the term “about” may also include a numeric value that is “exactly” the recited numeric value. In addition, any numeric value presented without modification will be appreciated to include numeric values “about” the recited numeric value, as well as include “exactly” the recited numeric value. Similarly, the term “substantially” means largely, but not wholly, the same form, manner or degree and the particular element will have a range of configurations as a person of ordinary skill in the art would consider as having the same function or result. When a particular element is expressed as an approximation by use of the term “substantially,” it will be understood that the particular element forms another embodiment.

The term “substrate,” as used herein, can broadly refer to any layer and/or surface upon which processing is desired. Thus, for example, a native oxide film on the surface of a silicon or silicon nitride substrate may itself be considered a substrate for the purposes of this discussion. Likewise, layers deposited on silicon, silicon nitride, or on other base substrates may likewise be considered substrates in some embodiments. For example, in some embodiments, a multi-layer stack may be formed, and then atomic layer deposition may be performed on the top layer, or a surface of the top layer, of the stack. In such a case, the top layer may be considered the substrate. In general, the layer or layers upon which the chemical precursor is deposited and/or which reacts with the chemical precursor can be considered the substrate layer(s). The material for the substrate may be any that may be appreciated by one of skill in the art in the field of electronics and/or semiconductors.

It will be understood that when an element is referred to as being “on” another element, layer, or substrate, etc., it can be directly on the other element, layer, or substrate, etc., or intervening elements, layers, or substrates, etc. may also be present. In contrast, when an element is referred to as being “directly on” another element, layer, or substrate, etc., there are no intervening elements present.

Unless otherwise defined, all technical and scientific terms used herein have the same meaning as commonly understood by one of ordinary skill in the art to which this inventive concept belongs.

The term atomic layer deposition, or ALD, as used herein, can broadly refer to the level of layer dimensional control in a deposition process, that can be achieved at the angstrom (Å) or sub-angstrom level. Thus, deposition of or growth of a layer through atomic layer deposition, or a cycle thereof, may generally correspond to the size of atoms and/or molecules. The average added layer thickness per cycle of ALD can be less than 1 Å (0.1 nm) per deposition cycle, for example, less than about 0.1 Å, about 0.1 Å, about 0.2 Å, about 0.3 Å, about 0.4 Å, about 0.5 Å, about 0.6 Å, about 0.7 Å, about 0.8 Å, or about 0.9 Å per cycle, or more than 1 Å per cycle, for example, about 1 Å, about 1.1 Å, about 1.2 Å, about 1.3 Å, about 1.4 Å, about 1.5 Å, about 1.6 Å, about 1.7 Å, about 1.8 Å, about 2 Å, about 3 Å, about 4 Å, about 5 Å, about 6 Å, about 7 Å, about 8 Å, about 9 Å, about 10 Å (1 nm), about 11 Å, about 12 Å, about 13 Å, about 14 Å, about 15 Å, about 16 Å, about 17 Å, about 18 Å, about 19 Å, or about 20 Å (2 nm) per cycle, or any number between about 0.1-30 Å per deposition cycle. In some embodiments, the average added layer thickness per cycle is between about 0.1-2 Å, about 0.2-2 Å per deposition cycle, about 0.3-2 Å, about 0.4-2 Å per deposition cycle, about 0.5-2 Å per deposition cycle, about 0.6-4 Å per deposition cycle, or about 0.1-4 Å per deposition cycle.

The layer prepared by the methods of the inventive concept may have a thickness of greater than or equal to 1 nm, greater than or equal to 2 nm, greater than or equal to 3 nm, greater than or equal to 4 nm, greater than or equal to 5 nm, greater than or equal to 6 nm, greater than or equal to 7 nm, greater than or equal to 8 nm, greater than or equal to 9 nm, greater than or equal to 10 nm, greater than or equal to 11 nm, greater than or equal to 13 nm, greater than or equal to 14 nm, greater than or equal to 15 nm, greater than or equal to 16 nm, greater than or equal to 18 nm, greater than or equal to 20 nm, in a range of greater than or equal to about 3 nm to about 20 nm, in a range of greater than or equal to about 5 nm to about 20 nm, or in a range of greater than or equal to about 5 nm to about 15 nm.

The temperature and/or pressure at which the methods of the present inventive concept are performed are not particularly limited. Nevertheless, in some embodiments, the temperature at which the ALD methods are performed between and including about 100° C. and about 300° C. In some embodiments, the temperature is between and including about 100° C. and about 250° C. In some embodiments, the temperature is between and including about 100° C. and about 200° C. In some embodiments, the pressure at which the ALD methods are performed at atmospheric or ambient pressures.

What is claimed is:

1. A compute-in-memory cell for use in an array of compute-in-memory cells, the compute-in-memory cell comprising:
a nonvolatile memory transistor having a gate terminal, a first terminal, and a second terminal, the nonvolatile memory transistor configured to retain a programmable state corresponding to a threshold voltage, and to selectively conduct in response to a control voltage applied to the gate terminal;
a capacitor electrically coupled in series with the nonvolatile memory transistor between a bit line and a sense node, the capacitor configured to accumulate electrical charge from the bit line during a charging phase when the nonvolatile memory transistor conducts;
wherein the bit line is configured to supply an input voltage during the charging phase, and the sense node is configured to store charge representative of a weight value associated with the compute-in-memory cell; and
wherein the sense node is further configured to transfer charge to or receive charge from one or more other sense nodes in the array during a compute phase, such that a voltage at the sense node reflects an analog output of a multiply-accumulate operation.

2. The compute-in-memory cell of claim 1, wherein the programmable state of the nonvolatile memory transistor corresponds to a binary weight value, and wherein the capacitor is configured to store either a nonzero charge or substantially no charge based on whether the nonvolatile memory transistor conducts during the charging phase.

3. The compute-in-memory cell of claim 1, wherein the programmable state of the nonvolatile memory transistor corresponds to a multi-bit weight value, and wherein the capacitor is configured to store one of a plurality of discrete charge levels corresponding to the multi-bit weight value.

4. The compute-in-memory cell of claim 1, wherein the nonvolatile memory transistor functions as a switch to control whether the capacitor accumulates charge during the charging phase based on the programmable state of the transistor.

5. The compute-in-memory cell of claim 1, wherein the nonvolatile memory transistor comprises a ferroelectric field-effect transistor having a gate stack including at least one ferroelectric dielectric layer configured to retain a polarization state corresponding to a threshold voltage.

6. The compute-in-memory cell of claim 1, wherein the charging phase comprises applying a sequence of input voltages to the bit line and a corresponding sequence of control voltages to the gate terminal of the nonvolatile memory transistor to incrementally charge the capacitor in accordance with a stored multi-bit weight value.

7. The compute-in-memory cell of claim 1, wherein the compute phase includes floating the bit line and connecting the sense node to one or more additional sense nodes through a shared line to perform analog charge redistribution across multiple cells.

8. The compute-in-memory cell of claim 1, wherein the capacitor is configured to be discharged to a baseline voltage prior to the charging phase.

9. The compute-in-memory cell of claim 1, wherein the sense node is configured to interface with peripheral circuitry to convert the voltage at the sense node into a digital output corresponding to a computed result.

10. The compute-in-memory cell of claim 1, wherein the programmable state of the nonvolatile memory transistor is retained without requiring periodic refresh, and wherein charge-based computation is performed without destructively reading the programmable state of the nonvolatile memory transistor.

11. A compute-in-memory array comprising a plurality of compute-in-memory cells arranged in rows and columns, each compute-in-memory cell comprising:
a nonvolatile memory transistor having a gate terminal, a first terminal, and a second terminal, the nonvolatile memory transistor configured to retain a programmable state corresponding to a threshold voltage and to selectively conduct in response to a control voltage applied to the gate terminal;
a capacitor electrically coupled in series with the nonvolatile memory transistor between a bit line and a sense node, the capacitor configured to accumulate electrical charge during a charging phase when the nonvolatile memory transistor conducts;
wherein the gate terminals of the nonvolatile memory transistors in a row are coupled to a common word line, and the bit lines and sense nodes are shared among compute-in-memory cells in respective columns;
wherein the compute-in-memory array is configured to perform a multiply-accumulate operation by applying control voltages to selected word lines and input voltages to selected bit lines to conditionally charge capacitors in the compute-in-memory cells based on stored weight values, and
wherein the sense nodes are configured to redistribute charge among capacitors during a compute phase such that a voltage at a sense node represents an analog output of the multiply-accumulate operation.

12. The compute-in-memory array of claim 11, wherein each compute-in-memory cell is configured to perform computation by accumulating electrical charge on its capacitor during a charging phase and by participating in charge redistribution across a plurality of sense nodes during a compute phase, such that a voltage level developed at a sense node corresponds to a cumulative charge value that represents the analog output of the multiply-accumulate operation.

13. The compute-in-memory array of claim 11, wherein each compute-in-memory cell is configured to store a multi-bit weight value, and wherein the capacitor in each compute-in-memory cell is configured to accumulate one of a plurality of discrete charge levels in response to a sequence of control voltages applied to the corresponding word line and a sequence of input voltages applied to the corresponding bit line.

14. The compute-in-memory array of claim 11, further comprising a peripheral circuit configured to sample the voltage at each sense node after charge redistribution, and to convert the sampled voltage into a digital value representing the analog output of the multiply-accumulate operation.

15. A method of performing a multiply-accumulate operation in a compute-in-memory array comprising a plurality of compute-in-memory cells, each compute-in-memory cell comprising a nonvolatile memory transistor and a capacitor, the method comprising:
storing a weight value by programming the nonvolatile memory transistor to a selected programmable state;
applying an input voltage to a bit line and a control voltage to a word line to cause the nonvolatile memory transistor to selectively conduct based on the programmable state;
accumulating charge on the capacitor during a charging phase when the nonvolatile memory transistor conducts; and
transferring charge to or receiving charge from one or more additional capacitors associated with other compute-in-memory cells via interconnected sense nodes during a compute phase, such that a voltage on a sense node represents a result of the multiply-accumulate operation.

16. The method of claim 15, wherein the nonvolatile memory transistor comprises a ferroelectric field-effect transistor having a gate stack including a ferroelectric dielectric layer configured to retain a polarization state corresponding to a threshold voltage of the transistor.

17. The method of claim 15, further comprising discharging the capacitor to a baseline voltage prior to the charging phase to initialize the compute-in-memory cell for the multiply-accumulate operation.

18. A method of performing multi-bit analog computation in a compute-in-memory array comprising a plurality of compute-in-memory cells, each compute-in-memory cell comprising a nonvolatile memory transistor and a capacitor, the method comprising:
programming the nonvolatile memory transistor to a programmable state corresponding to a multi-bit weight value;
applying, over a sequence of charging cycles, a plurality of control voltages to a word line associated with the nonvolatile memory transistor and a plurality of input voltages to a bit line, each control voltage corresponding to a bit level of the weight value;
charging the capacitor to one of a plurality of discrete charge levels based on the programmable state of the nonvolatile memory transistor; and
floating the bit line and transferring charge from the capacitor to a sense node for analog summation with charges from one or more other compute-in-memory cells, such that a resulting voltage at the sense node corresponds to a multi-bit MAC output.

19. The method of claim 18, wherein the nonvolatile memory transistor comprises a ferroelectric field-effect transistor having a gate stack including a ferroelectric dielectric layer configured to retain a polarization state corresponding to the programmable state of the nonvolatile memory transistor.

20. The method of claim 18, wherein charging the capacitor over the sequence of charging cycles comprises applying a first voltage level during a first cycle, a second voltage level during a second cycle, and a third voltage level during a third cycle, such that a total charge accumulated on the capacitor corresponds to the multi-bit weight value.
